(19) United States
(12) Patent Application Publication
(10) Pub. No.: US 2022/0293513 A1
(43) Pub. Date: Sep. 15, 2022

(54) POWER DECOUPLING METAL-INSULATOR-METAL CAPACITOR

(71) Applicant: QUALCOMM Incorporated, San Diego, CA (US)

(72) Inventors: Xia LI, San Diego, CA (US); Bin YANG, San Diego, CA (US); Haining YANG, San Diego, CA (US)

(21) Appl. No.: 17/198,941

(22) Filed: Mar. 11, 2021

(51) Int. Cl. H01L 23/522; H01L 21/8234; H02J 50/05; H01L 27/06; H01L 49/02; H01L 23/528

(52) U.S. Cl. CPC H01L 23/5223; H01L 21/823475; H02J 50/05; H01L 27/0694; H01L 28/40; H01L 23/5286

(57) ABSTRACT

Disclosed are examples of a device including a front side metallization portion having a front side BEOL. The device also includes a backside BEOL. The device also includes a substrate, where the substrate is disposed between the backside BEOL and the front side metallization portion. The device also includes a metal-insulator-metal (MIM) capacitor embedded in the backside BEOL.

### FIELD OF DISCLOSURE

This disclosure relates generally to semiconductor devices including capacitors, and more specifically, but not exclusively, to power decoupling metal-insulator-metal (MIM) capacitors and fabrication techniques thereof.

### BACKGROUND

High performance computation (HPC) processors, such as those for artificial intelligence (AI), are large and use capacitors for power decoupling to improve power IR drop for high performance high frequency computations. Multiple plate MIM capacitors can be used to decouple the power supply lines (Vdd) to improve processor performance. The MIM capacitors also may have other uses. However, conventional MIM capacitors may provide insufficient decoupling performance for HPC processors and other high performance systems.

Accordingly, there is a need for systems, apparatus, and methods that overcome the deficiencies of conventional capacitor configurations including the methods, systems and apparatuses provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In accordance with the various aspects disclosed herein, at least one aspect includes a device comprising: a first side back end of line (BEOL) metallization; a second side BEOL metallization; and a substrate disposed between the first side BEOL metallization and the second side BEOL metallization, where the second side BEOL metallization may include a metal-insulator-metal (MIM) capacitor.

In accordance with the various aspects disclosed herein, at least one aspect includes a method of fabricating a device. The method may include: forming a first side back end of line (BEOL) metallization on a substrate; forming a second side BEOL metallization on the substrate, where the substrate is disposed between the first side BEOL metallization and the second side BEOL metallization; and forming a metal-insulator-metal (MIM) capacitor in the second side BEOL metallization.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1A illustrates a device including a MIM capacitor in accordance with one or more aspects of the disclosure.

FIG. 1B illustrates a device including a 3D MIM capacitor in accordance with one or more aspects of the disclosure.

FIG. 1C illustrates a device including a 3D MIM capacitor in accordance with one or more aspects of the disclosure.

FIG. 2 illustrates a device including a MIM capacitor in accordance with one or more aspects of the disclosure.

FIG. 3 illustrates a device including a MIM capacitor in accordance with one or more aspects of the disclosure.

FIG. 4 illustrates a device including a MIM capacitor in accordance with one or more aspects of the disclosure.

FIG. 5 illustrates a device including a MIM capacitor in accordance with one or more aspects of the disclosure.

FIG. 6 illustrates a device including a MIM capacitor in accordance with one or more aspects of the disclosure.

FIG. 7 illustrates a device including a MIM capacitor in accordance with one or more aspects of the disclosure.

FIG. 8 illustrates a device including a MIM capacitor in accordance with one or more aspects of the disclosure.

FIG. 9 illustrates a device including a MIM capacitor in accordance with one or more aspects of the disclosure.

FIGS. 10A-10E illustrates a method for fabricating a device including a MIM capacitor in accordance with one or more aspects of the disclosure.

FIG. 11 illustrates a mobile device in accordance with at least one aspect of the disclosure.

FIG. 12 illustrates various electronic devices which may utilize one or more aspects of the disclosure.

FIG. 13 illustrates a flow chart for fabricating a device including a MIM capacitor in accordance with one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific aspects. Alternate aspects may be devised without departing from the scope of the teachings herein. Additionally, well-known elements of the illustrative aspects herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof

As discussed in the background, in high performance computing integrated circuit (IC) design, a large size decoupling capacitor can be used for VDD decoupling to reduce IR drop, from the front side. Further, the top metal layer (TME) MIM capacitors have less power decoupling effectiveness and larger IR drop. MIM capacitors can occupy the front side back end of line (BEOL) metal routing area, which is limited by chip area and routing.

IC level power distribution network (PDN) IR drop from front side of BEOL presents additional problems for IC scaling of 5 nm technologies. PDN IR drop degrades performance improvement from the reduced scale technologies, as technology scaling continues to shrink area and improve performance. Current process integration techniques do not allow for improved PDN IR drop when technology scales. Current fabrication technologies also do not allow vertical three dimensional (3D stack) integration.

In some aspects disclosed and discussed in further detail herein, backside back end of line (BEOL) metallization can enable configurations with a backside MIM capacitor with PDN connected to a power management IC (PMIC) to reduce IR drop, but does not require fine pitch which results in high fabrication cost. Additional aspects of the disclosure provide for improved MIM capacitor area at backside portion. In further aspects of the disclosure, double side BEOL configurations with a buried MIM capacitor can improve IC performance and scale IC area and package size in accordance with technology scaling.

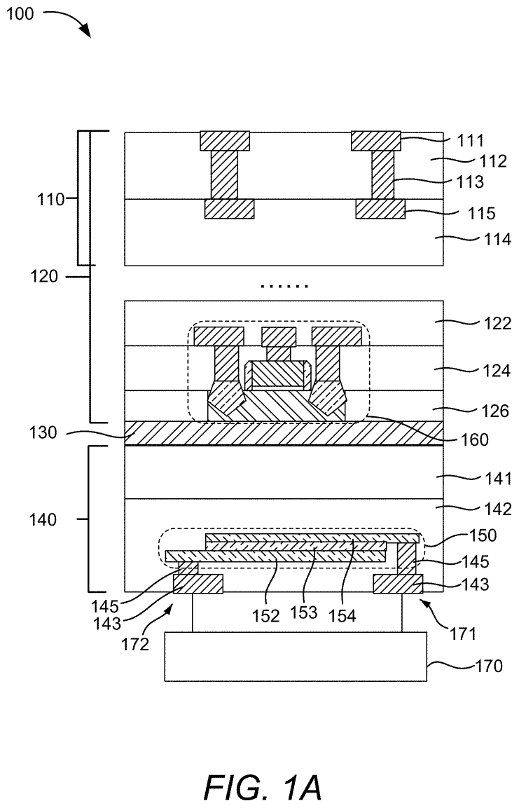

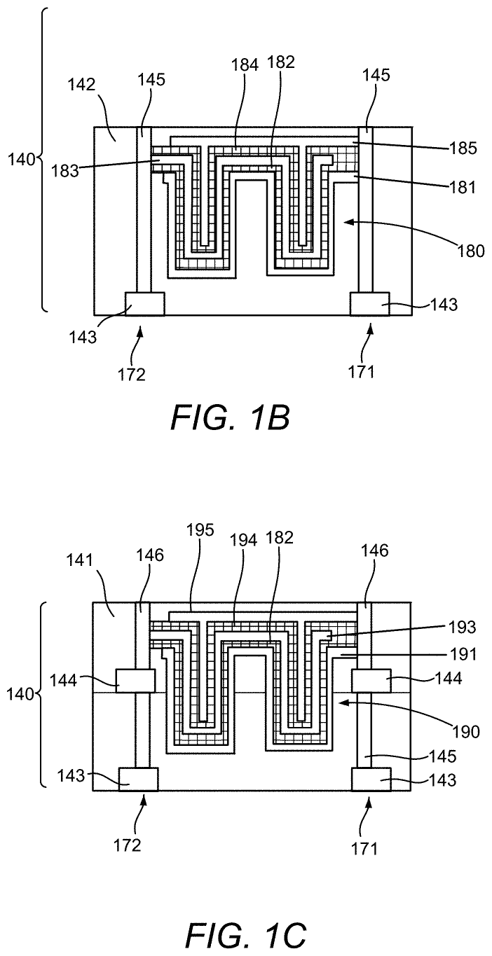

FIG. 1A illustrates a device 100 including a MIM capacitor 150 in accordance with one or more aspects of the disclosure. In some aspects, the device 100 may be a die, an integrated circuit, a package, and the like. Additionally, it will be appreciated that the device 100 may be an integrated device, of which only a portion is illustrated. As illustrated, the device 100 includes a front side metallization portion 120 having a first side (or front side) BEOL metallization 110. For convenience of explanation, the term “front side” BEOL metallization will generally be used herein. The front side BEOL metallization 110 may include one or more inter-metal dielectric (IMD) layers, which may have one or more metal layers and one or more vias. For example, IMD layer 112 may have a metal layer 111 and vias 113. The IMD layer 114 may have a metal layer 115 and portions of the metal layer 115 may be coupled to portions of the metal layer 111 using vias 113. In some aspects, the front side BEOL metallization 110 may also include one or more MIM capacitors (not illustrated), which can be formed in the front side BEOL metallization 110 using two or more metal layers (such as metal layers 111 and 115). However, it will be appreciated that any MIM capacitor formed in the front side BEOL metallization 110 will limit the area available for routing and interconnections.

As further illustrated in FIG. 1A, the device 100 includes front side metallization portion 120. The front side metallization portion 120 may include one or more IMD layers, interlayer dielectric (ILD) layers and shallow trench isolation (STI) portions for one or more transistors. For example, the front side metallization portion 120 may include IMD layer 122, ILD layer 124 and shallow trench isolation (STI) portion 126. Transistor 160 may be formed on substrate 130. The transistor 160 may be embedded in the front side metallization portion 120 and formed using metal layers and vias in the various layers using conventional techniques, so further details will not be discussed. The front side metallization portion 120 is disposed between the substrate 130 and the front side BEOL metallization 110. It will be appreciated that the substrate 130 is thinner than conventional designs. The substrate 130 thickness is on the range of 10 nm to 500 nm. The bulk silicon substrate used in conventional designs is thinned down to allow for a second side (or backside) BEOL metallization 140. For convenience of explanation the term “backside” BEOL metallization will generally be used herein. The backside BEOL metallization 140 is disposed on the substrate 130 on a side opposite the front side metallization portion 120 and front side BEOL metallization 110.

As illustrated, the backside BEOL metallization 140 may include one or more IMD layers, which may have one or more metal layers and one or more vias. For example, IMD layer 142 may have a metal layer 143 and vias 145. The IMD layer 141 may also have a metal layer and vias (not shown). In accordance with the various aspects disclosed, the backside BEOL metallization 140 may also include one or more metal-insulator-metal (MIM) capacitors 150, which can be formed in the backside BEOL metallization 140. The MIM capacitor 150 is embedded in the backside BEOL metallization 140. The MIM capacitor 150 includes a first plate 152 and a second plate 154 with a first insulator 153 disposed between the first plate 152 and the second plate 154. It will be appreciated that insulators as used herein in relation to the MIM capacitors include dielectric materials. The first plate 152 is coupled to a first power connection 171 which may be coupled to a power supply 170. The second plate 154 may be coupled to a second power connection 172, which may also be coupled to the power supply 170. In some aspects, the power supply may be located remote from the first power connection 171 and the second power connection 172.

In some aspects, the power supply local to or even in direct contact with the first power connection 171 and the second power connection 172. The first power connection 171 and the second power connection 172 may be formed, at least in part, from portions of the metal layer 143 and vias 145 in IMD layer 142. The first plate 152, second plate 154, metal layer 143 and vias 145 may be formed from any high conductive material, such as, copper (Cu), aluminum (AL), silver (Ag), gold (Au) or other conductive materials, alloys or combinations thereof. The first insulator 153 may be a high dielectric constant (high-k) dielectric material. The backside IMD layer 142 and IMD layer 141 may be a low dielectric constant (low-k) dielectric material. The one or more ILD layers may be formed of materials such as doped silicon dioxide (SiO₂), or its fluorine-doped, carbon-doped, and carbon-doped forms, as well as spin-on organic polymeric dielectrics such as polyimide (PI), polynorbornenes, benzocyclobutene (BCB), polytetrafluoroethylene (PTFE) and/or silicone based polymeric dielectrics.

In some aspects, the MIM capacitor may be a three-dimensional (3D) MIM capacitor formed in one or more metallization layers of the backside BEOL metallization 140. In some aspects, the 3D MIM capacitor is formed at least partially in two or more layers (e.g., 141 and 142) of the backside BEOL metallization 140. In some aspects, the 3D MIM capacitor may be formed in a generally serpentine shape. In some aspects, the 3D MIM capacitor may at least partially formed in a trench in one or more layers of the backside BEOL metallization 140.

For example, FIG. 1B illustrates an example of a 3D MIM capacitor 180 in accordance with one or more aspects of the disclosure. It will be appreciated the that only a portion of the backside BEOL metallization 140 is illustrated for the alternative aspect and the remaining portions are not illustrated to avoid redundancies. The 3D MIM capacitor 180 may be formed in the backside BEOL metallization 140 at least in part in intermetal dielectric (IMD) 142. The backside BEOL metallization 140 may be viewed as a back end of line (BEOL) layer where interconnects are formed. The backside BEOL metallization 140 may be differentiated from a device layer, which may be viewed a front end of line (BEOL) layer which comprises active components such as transistors. It will be appreciated that there can be multiple metallization layers in the backside BEOL metallization 140.

The 3D MIM capacitor 180 may be coupled to vias 145 formed in backside BEOL metallization 140, e.g., within the IMD 142. The area between the first and second vias may be referred to as a trench configuration of the 3D MIM capacitor 180. Contacts may be formed from the metal layer 143 and coupled to the vias 145 within the IMD 142. The vias 145 and contacts in metal layer 143 may be coupled to and form part of the first power connection 171 and the second power connection 172. The first power connection may be coupled to a first source (e.g., Vss) and the second power connection 172 may be coupled to a second source (e.g., Vdd). In an aspect, the contact in metal layer 143 and the vias 145 may be integrally formed from a same metal material (e.g., Cu).

The 3D MIM capacitor 180 may include two or more of plates and one or more capacitor dielectrics or insulators. FIG. 1B illustrates a 3D MIM capacitor 180 that comprises first plate 181, second plate 183, and third plate 185 (three plates) and first capacitor dielectric 182, and second capacitor dielectrics 184 (two capacitor dielectrics) disposed in a trench. The first plate 181 may be formed in the trench, the first capacitor dielectric 182 may be formed on the first plate 181, the second plate 183 may be formed on the first capacitor dielectric 182, the second capacitor dielectric 184 may be formed on the second plate 183, and the third plate 185 may be formed on the second capacitor dielectric 184.

It should be noted that terms or phrases such as “lower”, “upper”, “left”, “right”, “below”, “above”, “horizontal, “vertical”, etc. are used for convenience. Unless otherwise specifically indicated, such terms/phrased are not intended to indicate absolute orientations or directions. Also as indicated, terms “on” and “in contact with” may be used synonymously unless otherwise specifically indicated.

The first plate 181 may be coupled to the first power connection 171 at a first side (e.g., right side) of the trench, the second plate 183 may be coupled with the second power connection 172 at a second side (e.g., left side) of the trench. The first plate 181 may have a first serpentine shape. The second plate 183 may have a second shape such that there is a first serpentine gap between the first plate 181 and second plate 183, in which the first serpentine gap is substantially parallel with the first serpentine shape of the first plate 181. In an aspect, the second shape may be a second serpentine shape that is also substantially parallel with the first serpentine shape. The first capacitor dielectric 182 may be in the first serpentine gap between the first plate 181 and second plate 183. The serpentine shapes increase surface areas of the first plate 181 and second plate 183 and of the first capacitor dielectric 182. These factors enable the capacitance of the 3D MIM capacitor 180 to be increased, which can be beneficial in applications such as minimizing voltage droops.

The third plate 185 may be coupled with the first power connection 171 at the first side of the trench. The third plate 185 may have a third shape such that there is a second serpentine gap between the second plate 183 and third plate 185. For example, the second serpentine gap may be substantially parallel with the second serpentine shape of the second plate 183. In this instance, the third plate 185 may have one or more extensions that extend into one or more wells formed by the second plate 183. The second capacitor dielectric 184 may be in the second serpentine gap between the second plate 183 and third plate 185. The second capacitor dielectric 184 and the third plate 185 provide additional capacitance to the 3D MIM capacitor 180. In an aspect, the first capacitor dielectrics 182 and/or the second capacitor dielectric 184 may be high-k dielectrics while the IMD 142 may be a low-k dielectric.

FIG. 1C illustrates another example of a 3D MIM capacitor 190 in accordance with one or more aspects of the disclosure. The 3D MIM capacitor 190 may be similar to the 3D MIM capacitor 180 of FIG. 1B. One difference between them is that the 3D MIM capacitor 190 of FIG. 1C may be formed in multiple metallization layers of the backside BEOL metallization 140. For example, the 3D MIM capacitor 190 may be formed in a first metallization layer comprising a first IMD 141, vias 146 and metal layer 144, and in a second metallization layer comprising a second IMD 142, vias 145 and metal layer 143. The first power connection 171 and the second power connection 172 may be coupled to the 3D MIM capacitor 190 through metal layers 143 and 144 and vias 145 and 146. By forming the 3D MIM capacitor 190 in multiple metallization layers, surface areas of the plates and capacitor dielectrics can be increased even further, which means that the capacitances can also be increased.

In the illustrated configuration, the first plate 191 may be coupled to the first power connection 171 at a first side (e.g., right side) of the trench, the second plate 193 may be coupled with the second power connection 172 at a second side (e.g., left side) of the trench. The first plate 191 may have a first serpentine shape. The second plate 193 may have a second shape such that there is a first serpentine gap between the first plate 191 and second plate 193, in which the first serpentine gap is substantially parallel with the first serpentine shape of the first plate 191. In an aspect, the second shape may be a second serpentine shape that is also substantially parallel with the first serpentine shape. The first capacitor dielectric 192 may be disposed in the first serpentine gap between the first plate 191 and second plate 193. The serpentine shapes increase surface areas of the first plate 191 and second plate 193 and of the first capacitor dielectric 192. These factors enable the capacitance of the 3D MIM capacitor 190 to be increased, which can be beneficial in applications such as minimizing voltage droops.

The third plate 195 may be coupled with the first power connection 171 at the first side of the trench. The third plate 195 may have a third shape such that there is a second serpentine gap between the second plate 193 and third plate 195. For example, the second serpentine gap may be substantially parallel with the second serpentine shape of the second plate 193. In this instance, the third plate 195 may have one or more extensions that extend into one or more wells formed by the second plate 193. The second capacitor dielectric 194 may be in the second serpentine gap between the second plate 193 and third plate 195. The second capacitor dielectric 194 and the third plate 195 provide additional capacitance to the 3D MIM capacitor 190. In an aspect, the first capacitor dielectrics 192 and/or the second capacitor dielectric 194 may be high-k dielectrics while the IMD 142 and IMD 141 may be a low-k dielectric.

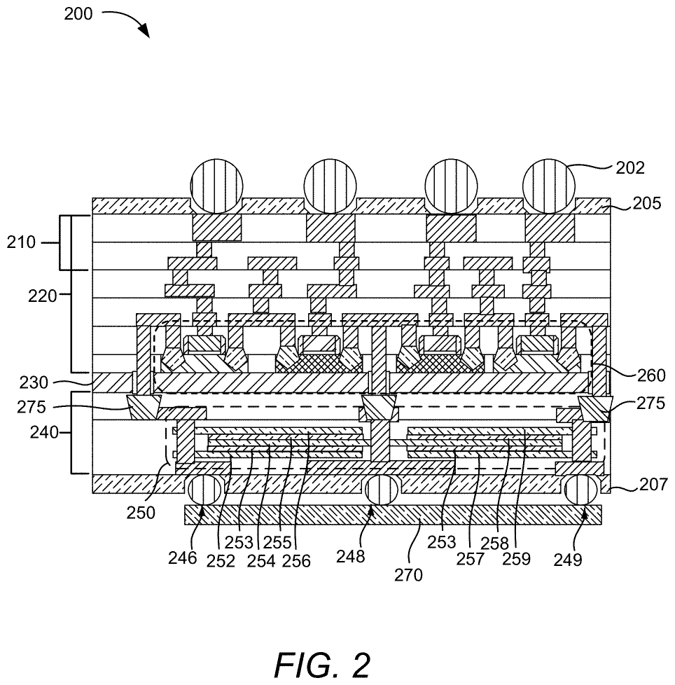

FIG. 2 illustrates a device 200 including another MIM capacitor 250 in accordance with one or more aspects of the disclosure. In some aspects, the device 200 may be a die, an integrated circuit, a package, and the like. Additionally, it will be appreciated that the device 200 may be a larger device, of which only a portion is illustrated. As illustrated, the device 200 includes a front side BEOL metallization 210. The front side BEOL metallization 210 may include one or more inter-metal dielectric (IMD) layers, which may have one or more metal layers and one or more vias. In some aspects, the front side BEOL metallization 210 may also include one or more MIM capacitors (not illustrated).

As further illustrated in FIG. 2, the device 200 includes front side metallization portion 220. The front side metallization portion 220 may include one or more IMD layers, ILD layers and shallow trench isolation (STI) portions for one or more transistors. Transistors 260 (four as illustrated) may be formed on substrate 230. The transistors 260 may be embedded in the front side metallization portion 220 and formed in part using metal layers and vias in the various layers using conventional techniques, so further details will not be discussed. The front side metallization portion 220 is disposed between the substrate 230 and front side BEOL metallization 210.

It will be appreciated that the substrate 230 is thinner than conventional designs. The substrate 230 thickness is on the range of 10 nm to 500 nm. The bulk silicon substrate used in conventional designs is thinned down to allow for a backside BEOL metallization 240. The backside BEOL metallization 240 is disposed on the substrate 230 on a side opposite the front side metallization portion 220 and front side BEOL metallization 210.

As illustrated, the backside BEOL metallization 240 may include one or more IMD layers, which may have one or more metal layers and one or more vias. In accordance with the various aspects disclosed, the backside BEOL metallization 240 may also include one or more MIM capacitors 250, which can be formed in the backside BEOL metallization 240. The MIM capacitor 250 is embedded in the backside BEOL metallization 240. The MIM capacitor 250 includes a first plate 252 and a second plate 254 with a first insulator 253 disposed between the first plate 252 and the second plate 254. The first plate 252 is coupled to a first power connection 246 which may be coupled to a power supply management chip (PSM) 270, which may be a power supply or power management IC (PMIC) directly coupled to the first power connection 246 and the second power connection 248. The second plate 254 may be coupled to the second power connection 248 and thus coupled to the PSM 270. A third plate 256 may be also coupled to the first power connection 246. A second insulator 255 is disposed between the third plate 256 and the second plate 254.

In addition, the MIM capacitor 250 may include a fourth plate 257 coupled to a third power connection 249 of the PSM 270. A fifth plate 259 may also be coupled to the third power connection 249 of the PSM 270. The second plate 254 is disposed between the fourth plate 257 and the fifth plate 259. The first insulator 253 is disposed between the fourth plate 257 and the second plate 254. A third insulator 258 is disposed between the fifth plate 259 and the second plate 254. In alternate aspects, the second insulator 255 may extend and be disposed between the fifth plate 259 and the second plate 254. The first plate 252, second plate 254, third plate 256, fourth plate 257 and fifth plate 259 may be formed from any high conductive material, such as, copper (Cu), aluminum (AL), silver (Ag), gold (Au) or other conductive materials, alloys or combinations thereof. The first insulator 253, second insulator 255 and third insulator 258 may be a high dielectric constant (high-k) dielectric material. Also, it will be appreciated, that the first insulator 253 is illustrated as being on both sides of the via in the second power connection 248 coupled to second plate 254 to emphasize that the first insulator may be formed from a common layer and then patterned and etched to provide an opening for the via coupled to the second plate 254. However, the various aspects disclosed herein are not limited to this configuration and each side of the first insulator 253 could be fabricated from separate insulators.

The first power connection 246, the second power connection 248 and the third power connection 249 may be formed as bumps/balls, and coupled at least in part, from portions of the metal layers and vias in the backside BEOL metallization 240. Additionally, the first power connection 246, the second power connection 248 and the third power connection 249 may include solder balls or other external connectors to couple to the PSM 270, through passivation layer 207 disposed on the backside BEOL metallization 240. In some aspects, the PSM 270 (e.g., PMIC) is directly coupled to the first power connection 246, the second power connection 248 and the third power connection 249. In some aspects, the first power connection 246 and the third power connection 249 are configured to be at a same potential. The first power connection 246 (and third power connection 249) may be configured to be at a positive potential (e.g., Vdd). The second power connection may be configured to be at a negative potential (e.g., Vss) or ground. As can be appreciated from the illustrated aspects, power is provided to the transistors 260 through various metal layers and vias in the backside BEOL metallization 240. In some aspects, the first power connection 246, the second power connection 248 and the third power connection 249 are coupled to respective embedded buried power rails (BPR) 275. In the illustrated configuration, the transistors 260 inputs and outputs (I/O) are conducted through various metal layers and vias in the front side metallization portion 220 and the front side BEOL metallization 210 to external connections 202 (which may be solder balls or any suitable connector) through passivation layer 205, which is disposed on the front side BEOL metallization 210.

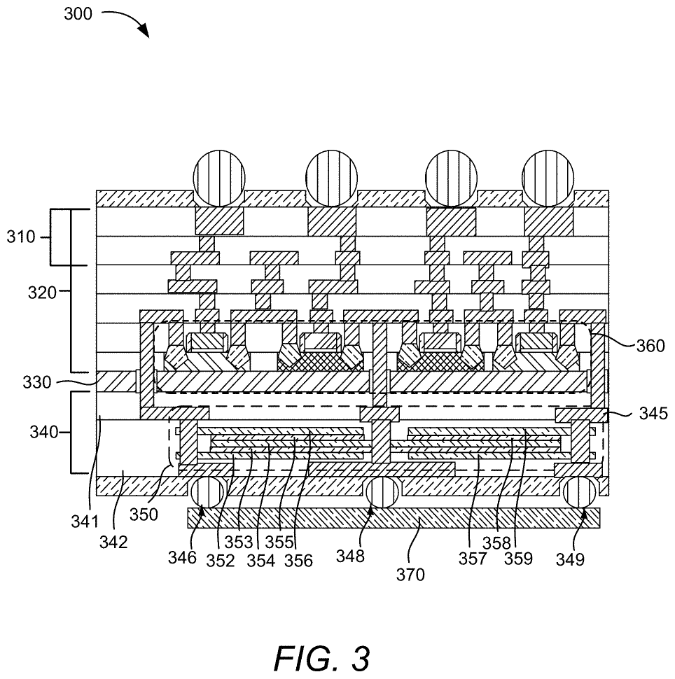

FIG. 3 illustrates a device 300 including a MIM capacitor 350 in accordance with one or more aspects of the disclosure. In some aspects, the device 300 may be a die, an integrated circuit, a package, and the like. Additionally, it will be appreciated that the device 300 may be a larger device, of which only a portion is illustrated. As illustrated, the device 300 includes a front side BEOL metallization 310. The front side BEOL metallization 310 may include one or more inter-metal dielectric (IMD) layers, which may have one or more metal layers and one or more vias. In some aspects, the front side BEOL metallization 310 may also include one or more MIM capacitors (not illustrated).

As further illustrated in FIG. 3, the device 300 includes front side metallization portion 320. The front side metallization portion 320 may include one or more IMD layers, ILD layers and shallow trench isolation (STI) portions for one or more transistors. Transistors 360 (four as illustrated) may be formed on substrate 330. The transistors 360 may be embedded in the front side metallization portion 320 and formed in part using metal layers and vias in the various layers. The transistors 360 may be fabricated using conventional techniques, so further details will not be discussed. The front side metallization portion 320 is disposed between the substrate 330 and front side BEOL metallization 310. It will be appreciated that the substrate 330 is thinner than conventional designs, as discussed in the foregoing.

As illustrated, the backside BEOL metallization 340 may include one or more IMD layers, which may have one or more metal layers and one or more vias. In accordance with the various aspects disclosed, the backside BEOL metallization 340 may also include one or more MIM capacitors 350, which can be formed in the backside BEOL metallization 340. The MIM capacitor 350 includes a first plate 352 and a second plate 354 with a first insulator 353 disposed between the first plate 352 and the second plate 354. In this configuration, it will be appreciated that the first insulator 353 may be a continuous layer and substantially follow the patterning of the second plate 354, as opposed to the separated first insulator discussed above in relation to first insulator 253, in FIG. 2. The first plate 352 is coupled to a first power connection 346 which may be coupled to a PSM 370, which may be a power supply or power management IC (PMIC), directly coupled to the first power connection 346 and the second power connection 348. The second plate 354 may be coupled to the second power connection 348 and thus coupled to the PSM 370. A third plate 356 may be also coupled to the first power connection 346. A second insulator 355 is disposed between the third plate 356 and the second plate 354.

In addition, the MIM capacitor 350 may include a fourth plate 357 coupled to a third power connection 349 of the PSM 370. A fifth plate 359 may also be coupled to the third power connection 349 of the PSM 370. The second plate 354 is disposed between the fourth plate 357 and the fifth plate 359. The first insulator 353 is disposed between the fourth plate 357 and the second plate 354. A third insulator 358 is disposed between the fifth plate 359 and the second plate 354. In alternate aspects, the second insulator 355 may extend and be disposed between the fifth plate 359 and the second plate 354. The first plate 352, second plate 354, third plate 356, fourth plate 357 and fifth plate 359 may be formed from any high conductive material, such as, copper (Cu), aluminum (AL), silver (Ag), gold (Au) or other conductive materials, alloys or combinations thereof. The first insulator 353, second insulator 355 and third insulator 358 may be a high dielectric constant (high-k) dielectric material.

The first power connection 346, the second power connection 348 and the third power connection 349 may be formed, at least in part, from portions of the metal layers and vias in the backside BEOL metallization 340. As can be appreciated from the illustrated aspects, power is provided to the transistors 360 through various metal layers and vias in the backside BEOL metallization 340. In some aspects, the first power connection 346, the second power connection 348 and the third power connection 349 are coupled to respective metal distribution portions 345. The metal distribution portions 345 may be used as to distribute power to the transistors 360, instead of a buried power rail, as provided in FIG. 2. In some aspects, the metal distribution portions 345 may be formed from a metal layer in a different IMD layer (e.g., IMD 341) than the one or more IMD layers (e.g., IMD 342) which contain the MIM capacitor 350.

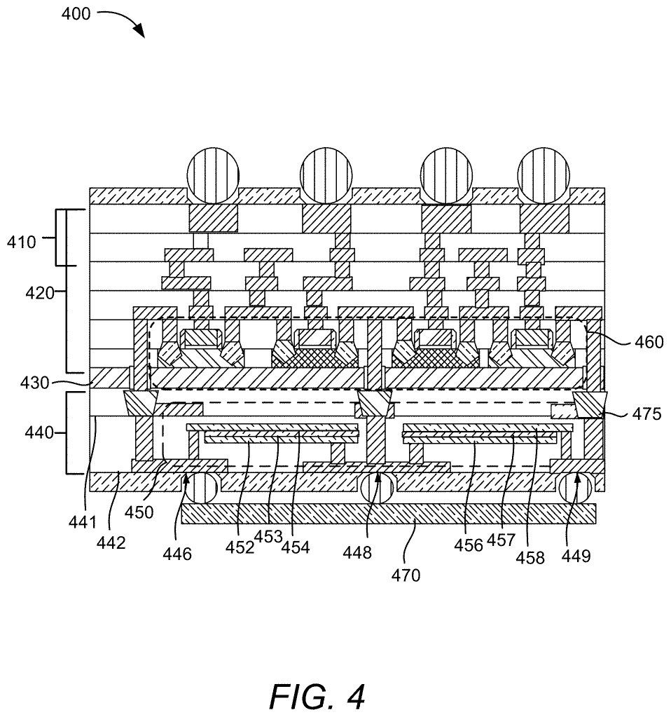

FIG. 4 illustrates a device 400 including a MIM capacitor 450 in accordance with one or more aspects of the disclosure. In some aspects, the device 400 may be a die, an integrated circuit, a package, and the like. Additionally, it will be appreciated that the device 400 may be a larger device, of which only a portion is illustrated. As illustrated, the device 400 includes a front side BEOL metallization 410. The front side BEOL metallization 410 may include one or more inter-metal dielectric (IMD) layers, which may have one or more metal layers and one or more vias. In some aspects, the front side BEOL metallization 410 may also include one or more MIM capacitors (not illustrated).

As further illustrated in FIG. 4, the device 400 includes front side metallization portion 420. The front side metallization portion 420 may include one or more IMD layers, ILD layers and shallow trench isolation (STI) portions for one or more transistors. Transistors 460 (four as illustrated) may be formed on substrate 430. The transistors 460 may be embedded in the front side metallization portion 420 and formed in part using metal layers and vias in the various layers. The transistors 460 may be fabricated using conventional techniques, so further details will not be discussed. The front side metallization portion 420 is disposed between the substrate 430 and front side BEOL metallization 410. It will be appreciated that the substrate 430 is thinner than conventional designs, as discussed in the foregoing.

As illustrated, the backside BEOL metallization 440 may include one or more IMD layers, which may have one or more metal layers and one or more vias. In accordance with the various aspects disclosed, the backside BEOL metallization 440 may also include one or more MIM capacitors 450, which can be formed in the backside BEOL metallization 440. The MIM capacitor 450 includes a first plate 452 and a second plate 454 with a first insulator 453 disposed between the first plate 452 and the second plate 454. The first plate 452 is coupled to a first power connection 446 which may be coupled to a PSM 470, which may be a PSM die 470 (or power management IC (PMIC)) directly coupled to the first power connection 446 and the second power connection 448. The second plate 454 may be coupled to the second power connection 448 and thus coupled to the PSM 470.

In addition, the MIM capacitor 450 may include a third plate 456 coupled to a third power connection 449 of the PSM 470. A fourth plate 458 coupled to the second power connection 448 of the PSM 470. A second insulator 457 is disposed between the third plate 456 and the fourth plate 458. In alternate aspects, the second insulator 457 may be a portion of the first insulator 453. Likewise, the third plate 456 may be a portion of the first plate 452 and fourth plate 458 may be a portion of the second plate 454. Accordingly, in this aspect, the MIM capacitor 450 would only have the first plate 452, the first insulator 453 and the second plate 454. The first insulator 453 is disposed between the first plate 452 and the second plate 454. The first plate 452 would be coupled to both the first power connection 446 and third power connection 449. In some aspects, the second plate 454 may be coupled to the second power connection 448 by one or more vias of the second power connection 448.

The first plate 452, second plate 454, third plate 456 and fourth plate 458 may be formed from any high conductive material, such as, copper (Cu), aluminum (AL), silver (Ag), gold (Au) or other conductive materials, alloys or combinations thereof. The first insulator 453 and second insulator 455 may be a high dielectric constant (high-k) dielectric material.

In some aspects, the first power connection 446 and the third power connection 449 are configured to be at a same potential. The first power connection 446 (and third power connection 449) may be configured to be at a positive potential (e.g., Vdd). The second power connection may be configured to be at a negative potential (e.g., Vss) or ground. As can be appreciated from the illustrated aspects, power is provided to the transistors 460 through various metal layers and vias in the backside BEOL metallization 440. In some aspects, the first power connection 446, the second power connection 448 and the third power connection 449 are coupled to respective embedded buried power rails (BPRs) 275. The BPRs 475 may be used to distribute power to the transistors 460. In some aspects, the BPRs 475 may be formed in a metal layer in a different IMD layer (e.g., IMD 441) than the one or more IMD layers (e.g., IMD 442) which contain the MIM capacitor 450.

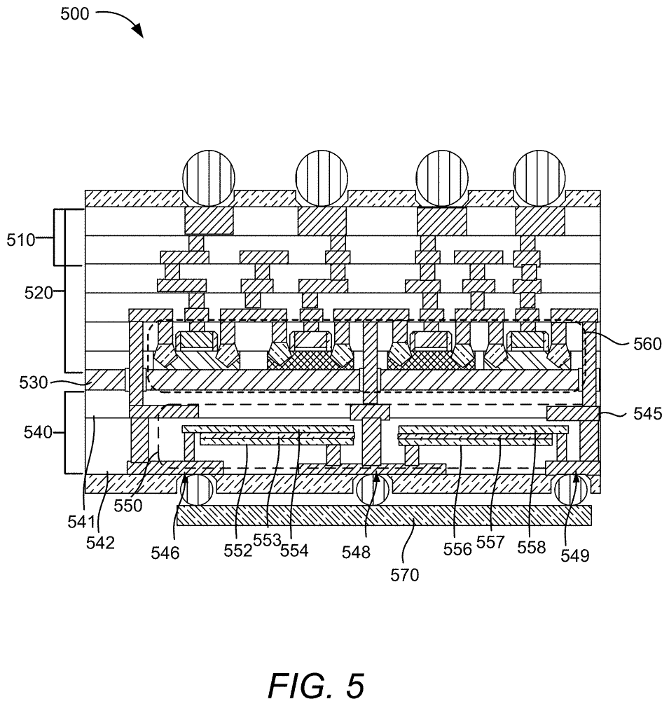

FIG. 5 illustrates a device 500 including a MIM capacitor 550 in accordance with one or more aspects of the disclosure. In some aspects, the device 500 may be a die, an integrated circuit, a package, and the like. Additionally, it will be appreciated that the device 500 may be a larger device, of which only a portion is illustrated. As illustrated, the device 500 includes a front side BEOL metallization 510. The front side BEOL metallization 510 may include one or more inter-metal dielectric (IMD) layers, which may have one or more metal layers and one or more vias. In some aspects, the front side BEOL metallization 510 may also include one or more MIM capacitors (not illustrated).

As further illustrated in FIG. 5, the device 500 includes front side metallization portion 520. The front side metallization portion 520 may include one or more IMD layers, ILD layers and shallow trench isolation (STI) portions for one or more transistors. Transistors 560 (four as illustrated) may be formed on substrate 530. The transistors 560 may be embedded in the front side metallization portion 520 and formed in part using metal layers and vias in the various layers. The transistors 560 may be fabricated using conventional techniques, so further details will not be discussed. The front side metallization portion 520 is disposed between the substrate 530 and front side BEOL metallization 510. It will be appreciated that the substrate 530 is thinner than conventional designs, as discussed in the foregoing.

As illustrated, the backside BEOL metallization 540 may include one or more IMD layers, which may have one or more metal layers and one or more vias. In accordance with the various aspects disclosed, the backside BEOL metallization 540 may also include one or more MIM capacitors 550, which can be formed in the backside BEOL metallization 540. The MIM capacitor 550 includes a first plate 552 and a second plate 554 with a first insulator 553 disposed between the first plate 552 and the second plate 554. The first plate 552 is coupled to a first power connection 546 which may be coupled to a PSM 570, which may be a power supply die 570 (or power management IC (PMIC)) directly coupled to the first power connection 546 and the second power connection 548. The second plate 554 may be coupled to the second power connection 548 and thus coupled to the PSM 570.

In addition, the MIM capacitor 550 may include a third plate 556 coupled to a third power connection 549 of the PSM 570. A fourth plate 558 coupled to the second power connection 548 of the PSM 570. A second insulator 557 is disposed between the third plate 556 and the fourth plate 558. In alternate aspects, the second insulator 557 may be a portion of the first insulator 553. Likewise, the third plate 556 may be a portion of the first plate 552 and fourth plate 558 may be a portion of the second plate 554. Accordingly, in this aspect, the MIM capacitor 550 would only have the first plate 552, the first insulator 553 and the second plate 554. The first insulator 553 is disposed between the first plate 552 and the second plate 554. The first plate 552 would be coupled to both the first power connection 546 and third power connection 549. In some aspects, the second plate 554 may be coupled to the second power connection 548 by one or more vias of the second power connection 548. The first plate 552, second plate 554, third plate 556 and fourth plate 558 may be formed from any high conductive material, such as, copper (Cu), aluminum (AL), silver (Ag), gold (Au) or other conductive materials, alloys or combinations thereof. The first insulator 553 and second insulator 555 may be a high dielectric constant (high-k) dielectric material.

In some aspects, the first power connection 546 and the third power connection 549 are configured to be at a same potential. The first power connection 546 (and third power connection 549) may be configured to be at a positive potential (e.g., Vdd). The second power connection may be configured to be at a negative potential (e.g., Vss) or ground. As can be appreciated from the illustrated aspects, power is provided to the transistors 560 through various metal layers and vias in the backside BEOL metallization 540. In some aspects, the first power connection 546, the second power connection 548 and the third power connection 549 are coupled to respective metal distribution portions 545. The metal distribution portions 545 may be used as to distribute power to the transistors 560, instead of the buried power rails, as illustrated in FIG. 4. In some aspects, the metal distribution portions 345 may be formed from a metal layer in a different IMD layer (e.g., IMD 541) than the one or more IMD layers (e.g., IMD 542) which contain the MIM capacitor 550.

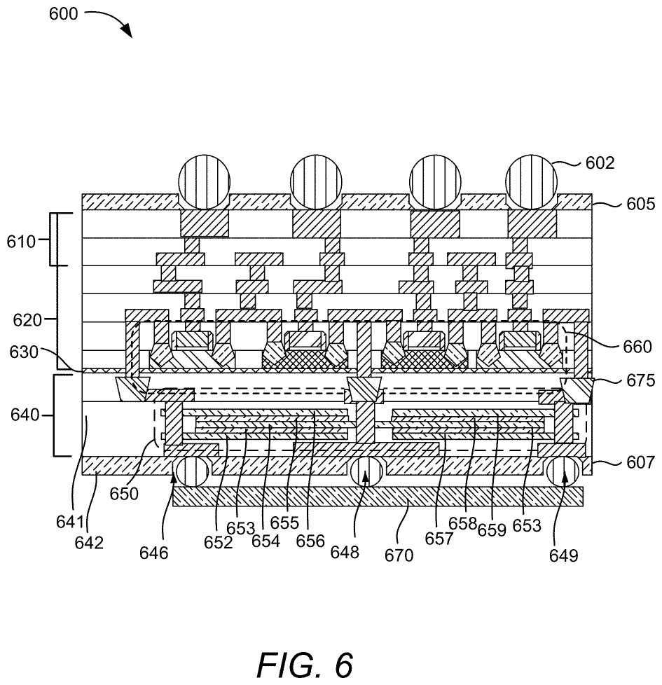

FIG. 6 illustrates a device 600 including a MIM capacitor 650 in accordance with one or more aspects of the disclosure. The device 600 is similar to device 200 in FIG. 2, but in this configuration the substrate 630 is a silicon on insulator (SOI) substrate. In some aspects, the device 600 may be a die, an integrated circuit, a package, and the like. Additionally, it will be appreciated that the device 600 may be a larger device, of which only a portion is illustrated. As illustrated, the device 600 includes a front side BEOL metallization 610, which is part of the front side metallization portion 620. The front side BEOL metallization 610 may include one or more inter-metal dielectric (IMD) layers, which may have one or more metal layers and one or more vias. In some aspects, the front side BEOL metallization 610 may also include one or more MIM capacitors (not illustrated).

As further illustrated in FIG. 6, the device 600 includes a front side metallization portion 620. The front side metallization portion 620 may include one or more IMD layers, ILD layers and shallow trench isolation (STI) portions for one or more transistors. Transistors 660 (four as illustrated) may be formed on substrate 630. The transistors 660 may be embedded in the front side metallization portion 620 and formed in part using metal layers and vias in the various layers using conventional techniques, so further details will not be discussed. It will be appreciated that the substrate 630 is thinner than conventional designs, as discussed in the foregoing.

As illustrated, the backside BEOL metallization 640 may include one or more IMD layers, which may have one or more metal layers and one or more vias. In accordance with the various aspects disclosed, the backside BEOL metallization 640 may also include one or more MIM capacitors 650, which can be formed in the backside BEOL metallization 640. The MIM capacitor 650 is embedded in the backside BEOL metallization 640. The MIM capacitor 650 includes a first plate 652 and a second plate 654 with a first insulator 653 disposed between the first plate 652 and the second plate 654. The first plate 652 is coupled to a first power connection 646 which may be coupled to a PSM 670. The PSM 670 may be a PSM die 670 (such as a power management IC (PMIC)) directly coupled to the first power connection 646 and the second power connection 648. The second plate 654 may be coupled to the second power connection 648 and thus coupled to the PSM 670. A third plate 656 may be also coupled to the first power connection 646. A second insulator 655 is disposed between the third plate 656 and the second plate 654.

In addition, the MIM capacitor 650 may include a fourth plate 657 coupled to a third power connection 649 of the PSM 670. A fifth plate 659 may also be coupled to the third power connection 649 of the PSM 670. The second plate 654 is disposed between the fourth plate 657 and the fifth plate 659. The first insulator 653 is disposed between the fourth plate 657 and the second plate 654. A third insulator 658 is disposed between the fifth plate 659 and the second plate 654. In alternate aspects, the second insulator 655 may extend and be disposed between the fifth plate 659 and the second plate 654. The first plate 652, second plate 654, third plate 656, fourth plate 657 and fifth plate 659 may be formed from any high conductive material, such as, copper (Cu), aluminum (AL), silver (Ag), gold (Au) or other conductive materials, alloys or combinations thereof. The first insulator 653, second insulator 655 and third insulator 658 may be a high dielectric constant (high-k) dielectric material. The IMD layers may be a low dielectric constant (low-k) dielectric material. The one or more ILD layers may be formed of materials such as doped silicon dioxide (SiO₂), or its fluorine-doped, carbon-doped, and carbon-doped forms, as well as spin-on organic polymeric dielectrics such as polyimide (PI), polynorbornenes, benzocyclobutene (BCB), polytetrafluoroethylene (PTFE) and/or silicone based polymeric dielectrics.

The first power connection 646, the second power connection 648 and the third power connection 649 may be formed, at least in part, from portions of the metal layers and vias in the backside BEOL metallization 640. Additionally, the first power connection 646, the second power connection 648 and the third power connection 649 may include solder balls or other external connectors to couple to the PSM 670, through passivation layer 607 disposed on the front side BEOL metallization 610. In some aspects, the PSM 670 (e.g., PMIC) is directly coupled to the first power connection 646, the second power connection 648 and the third power connection 649. In some aspects, the first power connection 646 and the third power connection 649 are configured to be at a same potential. The first power connection 646 (and third power connection 649) may be configured to be at a positive potential (e.g., Vdd). The second power connection may be configured to be at a negative potential (e.g., Vss) or ground. As can be appreciated from the illustrated aspects, power is provided to the transistors 660 through various metal layers and vias in the backside BEOL metallization 640. In some aspects, the first power connection 646, the second power connection 648 and the third power connection 649 are coupled to respective embedded buried power rails (BPRs) 675. In the illustrated configuration, the transistors 660 inputs and outputs (I/O) are conducted through various metal layers and vias in the front side metallization portion 620 and the front side BEOL metallization 610 to external connections 602 (which may be solder balls or any suitable connector) through passivation layer 605, which is disposed on the front side BEOL metallization 610.

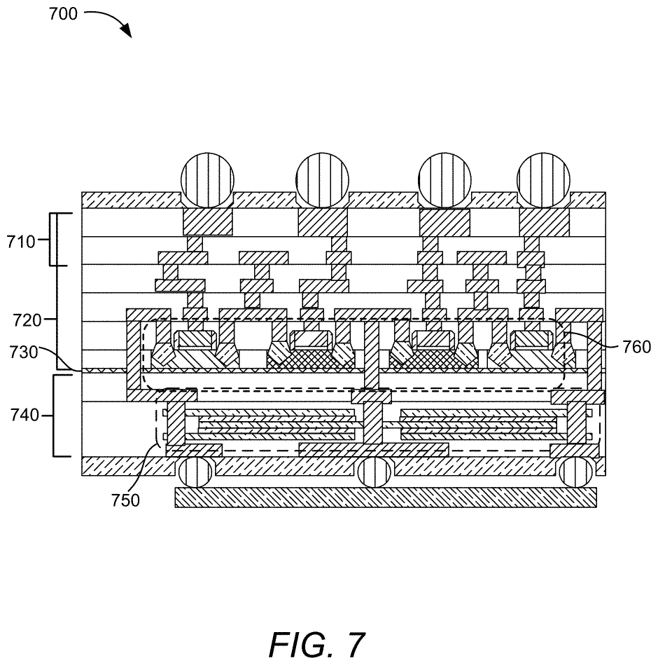

FIG. 7 illustrates a device 700 including a MIM capacitor 750 in accordance with one or more aspects of the disclosure. The device 700 is similar to device 300 in FIG. 3, but in this configuration the substrate 730 is a silicon on insulator (SOI) substrate. In some aspects, the device 700 may be a die, an integrated circuit, a package, and the like. Additionally, it will be appreciated that the device 700 may be a larger device, of which only a portion is illustrated. As illustrated, the device 700 includes a front side BEOL metallization 710, which is part of the front side metallization portion 720. The front side BEOL metallization 710 may include one or more inter-metal dielectric (IMD) layers, which may have one or more metal layers and one or more vias. In some aspects, the front side BEOL metallization 710 may also include one or more MIM capacitors (not illustrated).

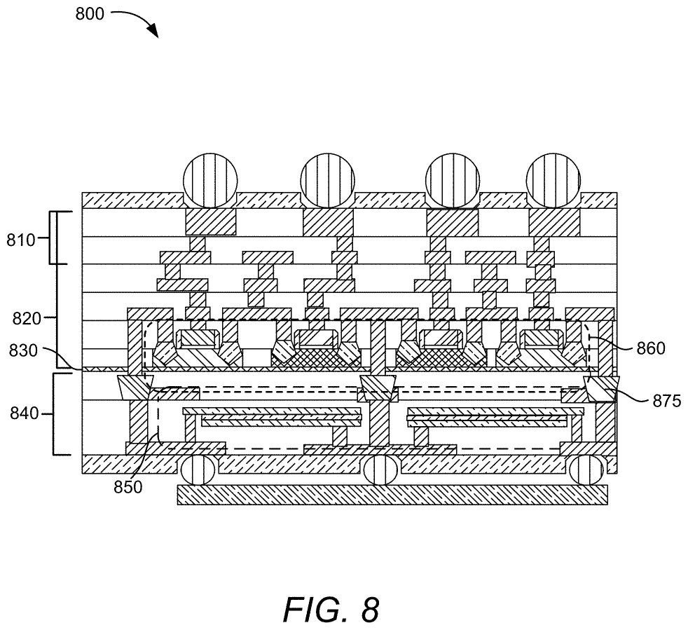

FIG. 8 illustrates a device 800 including a MIM capacitor 850 in accordance with one or more aspects of the disclosure. The device 800 includes BPRs 875 and is similar to device 400 in FIG. 4, but in this configuration the substrate 830 is a silicon on insulator (SOI) substrate. In some aspects, the device 800 may be a die, an integrated circuit, a package, and the like. Additionally, it will be appreciated that the device 800 may be a larger device, of which only a portion is illustrated. As illustrated, the device 800 includes a front side BEOL metallization 810, which is part of the front side metallization portion 820. The front side BEOL metallization 810 may include one or more inter-metal dielectric (IMD) layers, which may have one or more metal layers and one or more vias. In some aspects, the front side BEOL metallization 810 may also include one or more MIM capacitors (not illustrated).

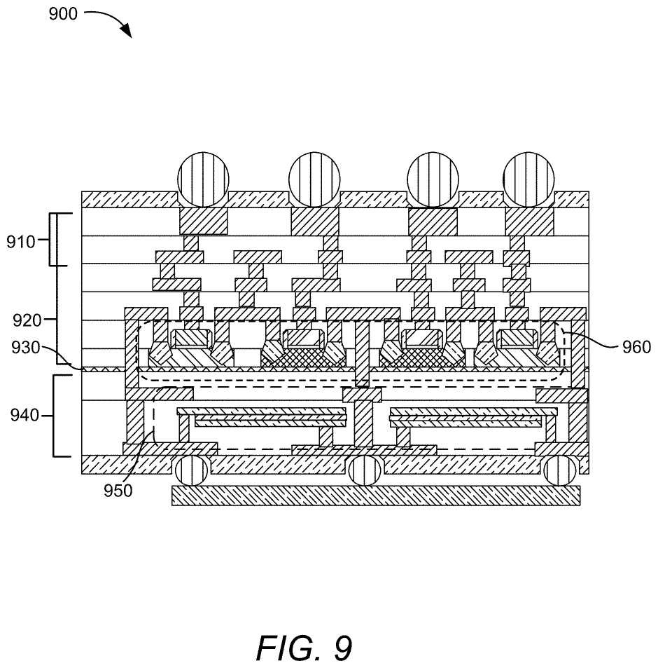

FIG. 9 illustrates a device 900 including a MIM capacitor 950 in accordance with one or more aspects of the disclosure. The device 900 does not have BPRs and is similar to device 500 in FIG. 5, but in this configuration the substrate 930 is a silicon on insulator (SOI) substrate. In some aspects, the device 900 may be a die, an integrated circuit, a package, and the like. Additionally, it will be appreciated that the device 900 may be a larger device, of which only a portion is illustrated. As illustrated, the device 900 includes a front side BEOL metallization 910, which is part of the front side metallization portion 920. The front side BEOL metallization 910 may include one or more inter-metal dielectric (IMD) layers, which may have one or more metal layers and one or more vias. In some aspects, the front side BEOL metallization 910 may also include one or more MIM capacitors (not illustrated).

In order to fully illustrate aspects of the design of the present disclosure, methods of fabrication are presented. Other methods of fabrication are possible, and discussed fabrication methods are presented only to aid understanding of the concepts disclosed herein.

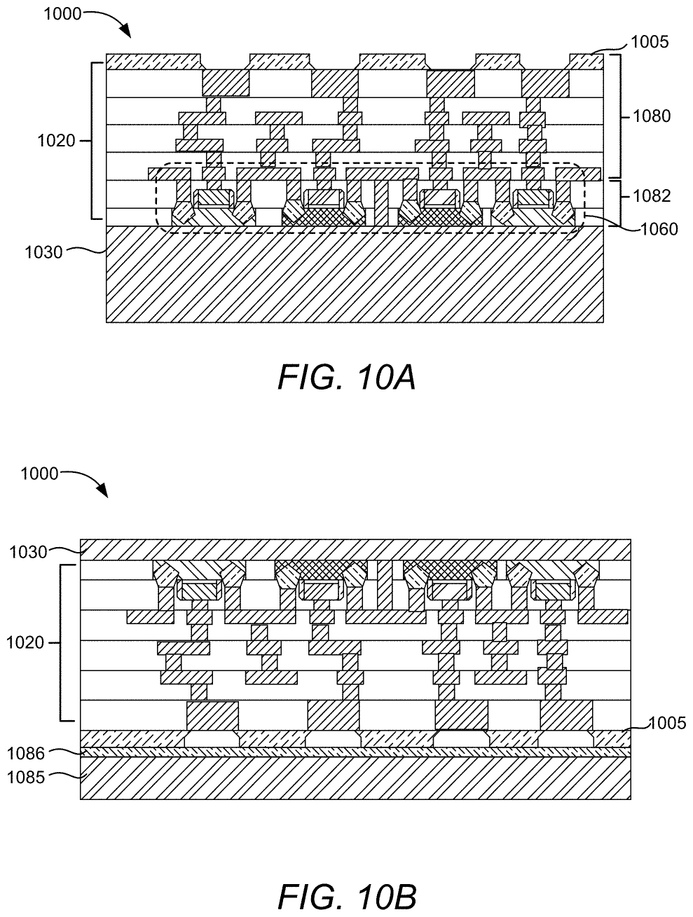

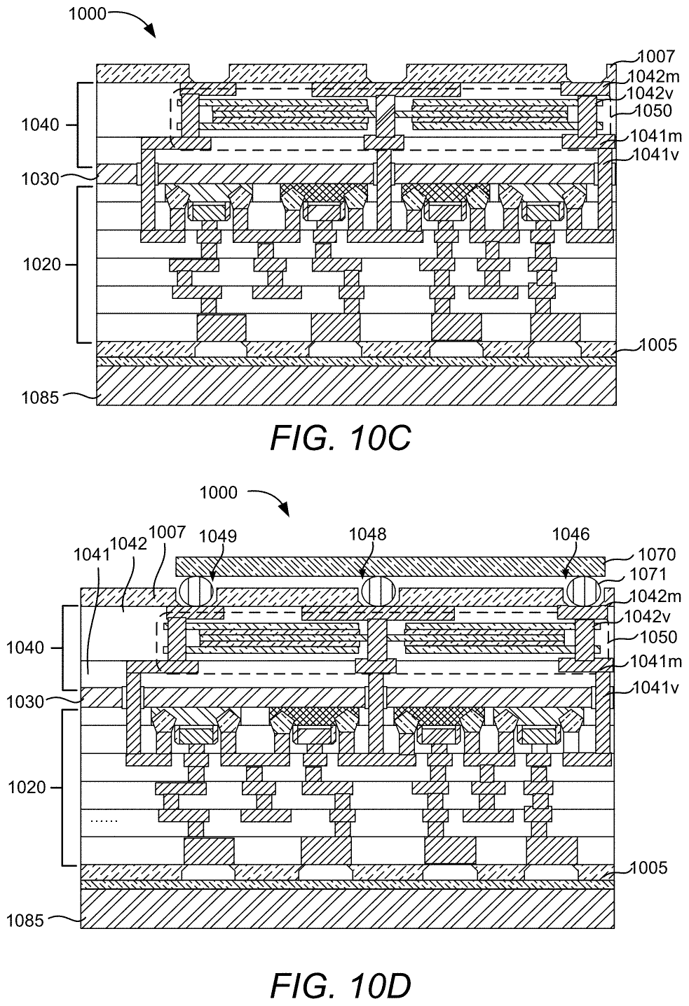

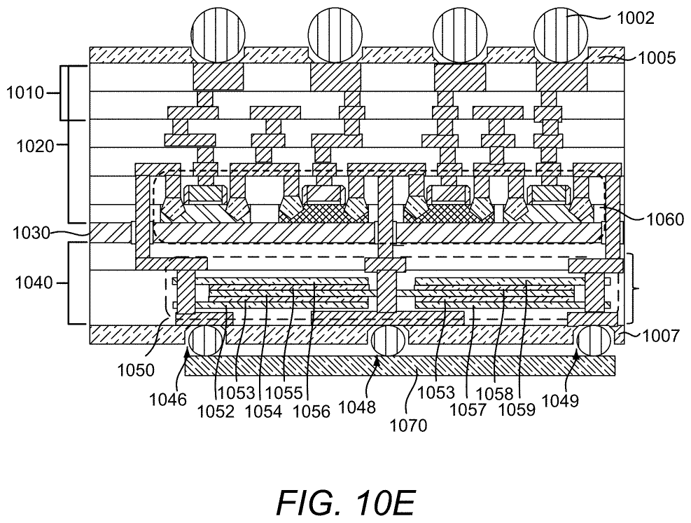

FIGS. 10A-10E illustrate example portions of fabricating a device 1000, such as the devices illustrated in FIGS. 1-4, in accordance with one or more aspects of the disclosure. FIGS. 10A-10E generally illustrate cross-sectional views of the various stages of fabrication.

FIG. 10A illustrates a portion of a fabrication process of the device 1000 in accordance with one or more aspects of the disclosure. As shown in FIG. 10A, the process can begin with a front side metallization portion 1020. The front side metallization portion 1020 may include one or more IMD layers, one or more ILD layers and shallow trench isolation (STI) portions for one or more transistors.

Transistors 1060 (four as illustrated) may be formed on substrate 1030. The transistors 1060 may be embedded in the front side metallization portion 1020 and formed in part using metal layers and vias in the various layers using conventional techniques. For example, the transistors 1060 may be formed in a first portion 1082 of the front side metallization portion 1020. The first portion 1082 may undergo a front end of line (FEOL) process including selecting the type of substrate 1030 to be used, chemical mechanical polishing (CMP), shallow trench isolation (STI), well formation, gate module formation, and source and drain formation. Additionally, in first portion 1082, a middle end of line (MEOL) process may be performed after the FEOL process, which may include processes such as gate contact formation. Back end of line (BEOL) processing may be performed on a second portion 1080 of the front side metallization portion 1020 where the individual devices (e.g., transistors 1060 and other active and passive devices) are interconnected internally and to external connections using the metal layers and vias in the front side metallization portion 1020. A passivation layer may be deposited on the front side metallization portion 1020 and patterned to have openings to connect to pads formed in the front side metallization portion 1020. As noted above, these processes are known and therefore will not be described in detail.

FIG. 10B illustrates a further portion of the fabrication process of a device 1000 in accordance with one or more aspects of the disclosure. As shown in FIG. 10B, the process can continue with a front side metallization portion 1020 being formed with a passivation layer 1005 being disposed on one side of front side metallization portion 1020 opposite the substrate 1030. In this portion of the fabrication process, a support wafer 1085 (e.g., glass wafer) is attached to the passivation layer 1005 using an adhesive 1086 or other suitable technique for attaching the support wafer 1085. Additionally, the front side metallization portion 1020, substrate 1030 and passivation layer 1005 are flipped over so that the substrate 1030 can be reduced in thickness. The reduction can be performed by grinding or any suitable technique. It will be appreciated that the substrate 1030 is made thinner than conventional designs, as discussed above. The substrate 1030 thickness, after reduction, is on the range of 10 nm to 500 nm

FIG. 10C illustrates a further portion of the fabrication process of a device 1000 in accordance with one or more aspects of the disclosure. As shown in FIG. 10C, the process can continue with a front side metallization portion 1020 being formed with a passivation layer 1005 being disposed on one side of front side metallization portion 1020 opposite the substrate 1030. The support wafer 1085 remains attached to the passivation layer 1005. Additionally, the front side metallization portion 1020, substrate 1030 and passivation layer 1005 are flipped over. The thickness of the substrate 1030 has been reduced to allow for a backside BEOL metallization 1040 to be formed, in this portion of the fabrication process. The process continues with forming the backside BEOL metallization 1040 using conventional BOEL processing. The backside BEOL metallization 1040 is disposed on the substrate 1030 on a side opposite the front side metallization portion 1020 and front side BEOL metallization 1010.

As illustrated, the backside BEOL metallization 1040 may include one or more IMD layers, which may have one or more metal layers and one or more vias. For example, a first IMD layer 1041 may be deposited, a first metal layer 1041m patterned and vias 1041v formed in the first IMD layer 1041 to connect portions of the first metal layer 1041m to transistors in the front side metallization portion 1020. A second IMD layer 1042 may be deposited, a second metal layer 1042m patterned and vias 1042v formed in the second IMD layer 1042 to connect portions of the first metal layer 1041m to portions of the second metal layer 1042m, which may be formed as pads under openings in the passivation layer 1007 deposited on the backside BEOL metallization 1040. The BEOL metallization process may further be used to form one or more MIM capacitors 1050. As noted above, the BEOL metallization processes are conventional so the fabrication process details will not be discussed in detail.

FIG. 10D illustrates a further portion of the fabrication process of a device 1000 in accordance with one or more aspects of the disclosure. As shown in FIG. 10D, the process can continue with the front side metallization portion 1020 being formed with the passivation layer 1005 being disposed on one side of front side metallization portion 1020 opposite the substrate 1030. The support wafer 1085 remains attached to the passivation layer 1005. Additionally, the front side metallization portion 1020, substrate 1030, passivation layer 1005 and backside BEOL 1040 with passivation layer 1007 deposited remain flipped over. The process continues with depositing contacts 1071 on pads formed from the second metal layer 1042m. The contacts 1071, in some aspects, may also be directly couple to a power supply die 1070 (such as a PMIC). It will be appreciated that portion of the contacts 1071, second metal layer 1042m and vias 1042v may form at least part of the first power connection 1046, second power connection 1048 and third power connection 1049. The first power connection 1046, second power connection 1048 and third power connection 1049 provide power to the transistors 1060 and the MIM capacitor 1050 is also coupled to the power connections (1046, 1048 and 1049) to allow for electrical decoupling and smoothing of the power supply voltage to avoid excessive IR drop. The coupling of the MIM capacitor 1050 to the power connections (1046, 1048 and 1049) is described in further detail below.

FIG. 10E illustrates a further portion of the fabrication process of a device 1000 in accordance with one or more aspects of the disclosure. As shown in FIG. 10E, the process can continue with the front side metallization portion 1020 being formed with the passivation layer 1005 being disposed on one side of front side metallization portion 1020 opposite the substrate 1030. Additionally, the front side metallization portion 1020, substrate 1030, passivation layer 1005 and backside BEOL metallization 1040 with passivation layer 1007 are formed. Further, the MIM capacitor 1050 is formed in the backside BEOL metallization 1040 and power supply die 1070 is directly coupled to the backside BEOL metallization 1040. The process continues with the support wafer being removed from the passivation layer 1005 and the device being flipped back over to where the front side metallization portion 1020 is oriented up. The process further continues with depositing connectors 1002 through openings in passivation layer 1005 on pads formed from portions of a top metal layer in a front side BEOL metallization 1010 of the front side metallization portion 1020. The connectors 1002 may be solder balls, copper pillars or any suitable connector. In the illustrated configuration, the transistors 1060 inputs and outputs (I/O) are conducted through various metal layers and vias in the front side metallization portion 1020 and the front side BEOL metallization 1010 to connectors 1002 through passivation layer 1005, which is disposed on the front side BEOL metallization 1010.

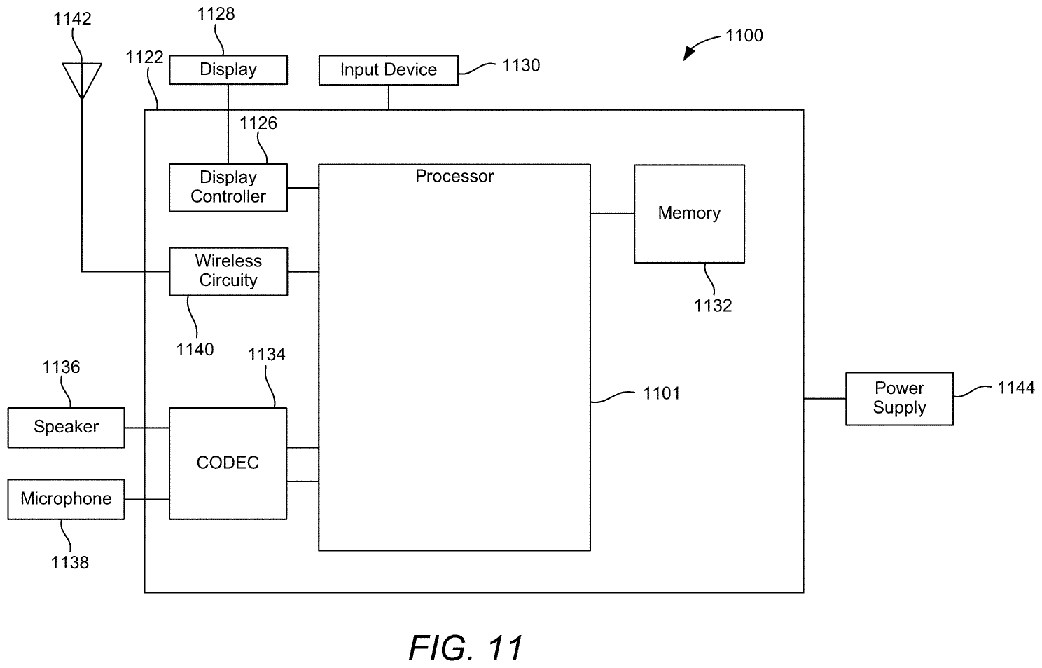

FIG. 11 illustrates an exemplary mobile device in accordance with some examples of the disclosure. Referring now to FIG. 11, a block diagram of a mobile device that is configured according to exemplary aspects is depicted and generally designated mobile device 1100. In some aspects, mobile device 1100 may be configured as a wireless communication device. As shown, mobile device 1100 includes processor 1101. Processor 1101 may be communicatively coupled to memory 1132 over a link, which may be a die-to-die or chip-to-chip link. Mobile device 1100 also includes display 1128 and display controller 1126, with display controller 1126 coupled to processor 1101 and to display 1128.

In some aspects, FIG. 11 may include coder/decoder (CODEC) 1134 (e.g., an audio and/or voice CODEC) coupled to processor 1101; speaker 1136 and microphone 1138 coupled to CODEC 1134; and wireless circuits 1140 (which may include a modem, RF circuitry, filters, etc., which may be implemented using one or more devices including a MIM capacitor in a backside BEOL metallization, as disclosed herein) coupled to wireless antenna 1142 and to processor 1101.

In a particular aspect, where one or more of the above-mentioned blocks are present, processor 1101, display controller 1126, memory 1132, CODEC 1234, and wireless circuits 1140 can be included in a system-in-package or system-on-chip device 1122 which may be implemented using the which may be implemented using one or more devices including a MIM capacitor in a backside BEOL metallization, as disclosed herein. Input device 1130 (e.g., physical or virtual keyboard), power supply 1144 (e.g., buried), display 1128, input device 1130, speaker 1136, microphone 1138, wireless antenna 1142, and power supply 1144 may be external to system-on-chip device 1122 and may be coupled to a component of system-on-chip device 1122, such as an interface or a controller.

It should be noted that although FIG. 11 depicts a mobile device 1100, processor 1101 and memory 1132 may also be integrated into a set top box, a music player, a video player, an entertainment unit, a navigation device, a personal digital assistant (PDA), a fixed location data unit, a computer, a laptop, a tablet, a communications device, a mobile phone, or other similar devices.

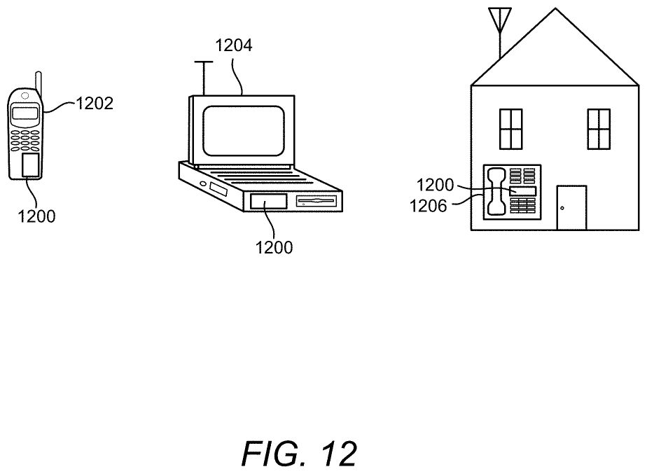

FIG. 12 illustrates various electronic devices that may be integrated with any of the aforementioned integrated device or semiconductor device accordance with various examples of the disclosure. For example, a mobile phone device 1202, a laptop computer device 1204, and a fixed location terminal device 1206 may each be considered generally user equipment (UE) and may include a device 1200 including a MIM capacitor in a backside BEOL metallization as described herein. The device 1200 may be, for example, any of the integrated circuits, dies, integrated devices, integrated device packages, integrated circuit devices, device packages, integrated circuit (IC) packages, package-on-package devices described herein. The devices 1202, 1204, 1206 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

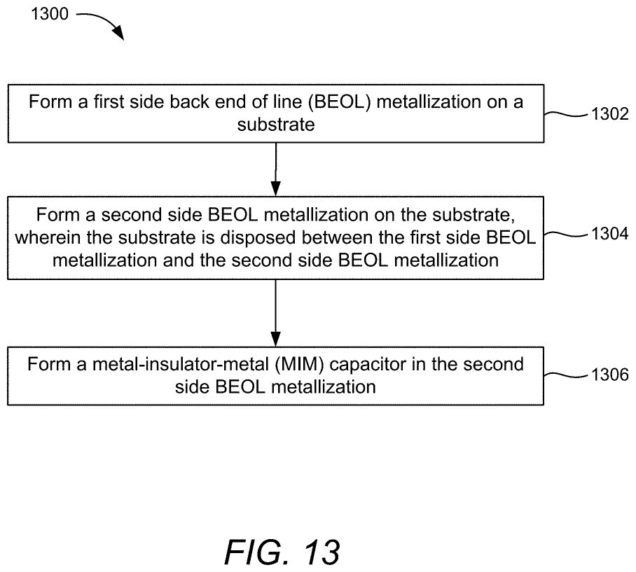

It will be appreciated from the foregoing that there are various methods for fabricating devices including a MIM capacitor in a backside BEOL metallization as disclosed herein. FIG. 13 illustrates a flowchart of an example method 1300 for fabricating device including a metal-insulator-metal (MIM) capacitor embedded in the backside BEOL metallization in accordance with at least one aspect disclosed. In block 1302, the fabrication process can include forming a first side back end of line (BEOL) metallization on a substrate. In block 1304, the fabrication process can further include forming a second side BEOL metallization on the substrate, where the substrate is disposed between the first side BEOL metallization and the second side BEOL metallization. In block 1306, the fabrication process can further include forming a metal-insulator-metal (MIM) capacitor in the second side BEOL metallization.

It will be appreciated from the foregoing disclosure that additional processes for fabricating the various aspects disclosed herein will be apparent to those skilled in the art and a literal rendition of the processes discussed above will not be provided or illustrated in the included drawings.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

One or more of the components, processes, features, and/or functions illustrated in FIGS. 1-13 may be rearranged and/or combined into a single component, process, feature or function or incorporated in several components, processes, or functions. Additional elements, components, processes, and/or functions may also be added without departing from the disclosure. It should also be noted that FIGS. 1-13 and corresponding description in the present disclosure are not limited to dies and/or integrated circuits (ICs). In some implementations, FIGS. 1-13 and its corresponding description may be used to manufacture, create, provide, and/or produce integrated devices. In some implementations, a device may include a die, an integrated device, a die package, an integrated circuit (IC), a device package, an IC package, a wafer, a semiconductor device, a package on package (PoP) device, and/or an interposer.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described herein can be configured to perform at least a portion of a method described herein.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those skilled in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an insulator and a conductor). Furthermore, it is also intended that aspects of a clause can be included in any other independent clause, even if the clause is not directly dependent on the independent clause.

Implementation examples are described in the following numbered clauses:

Clause 1. A device comprising: a first side back end of line (BEOL) metallization; a second side BEOL metallization; and a substrate disposed between the first side BEOL metallization and the second side BEOL metallization, wherein the second side BEOL metallization comprises a metal-insulator-metal (MIM) capacitor.

Clause 2. The device of clause 1, wherein the MIM capacitor comprises: a first plate coupled to a first power connection; a second plate coupled to a second power connection; and a first insulator disposed between the first plate and the second plate.

Clause 3. The device of clause 2, wherein the MIM capacitor further comprises a third plate coupled to the first power connection; and a second insulator disposed between the third plate and the second plate.

Clause 4. The device of clause 3, wherein the MIM capacitor further comprises: a fourth plate coupled to a third power connection; and a fifth plate coupled to the third power connection, wherein the second plate is disposed between the fourth plate and the fifth plate.

Clause 5. The device of clause 4, wherein the first insulator is disposed between the fourth plate and the second plate, and wherein a third insulator is disposed between the fifth plate and the second plate.

Clause 6. The device of clause 4, wherein the first insulator is disposed between the fourth plate and the second plate, and wherein the second insulator is disposed between the fifth plate and the second plate.

Clause 7. The device of any of clauses 2 to 6, wherein the first power connection is configured to be at a positive potential and wherein the second power connection is configured to be at a negative potential or ground.

Clause 8. The device of any of clauses 2 to 7, wherein the first insulator comprises a high dielectric constant (high-k) dielectric material and the first plate, the first insulator, and the second plate are disposed in an inter-metal dielectric (IMD) layer and wherein the IMD layer comprises a low dielectric constant (low-k) dielectric material.

Clause 9. The device of any of clauses 1 to 8, further comprising: at least one transistor formed on the substrate on a same side as the first side BEOL metallization.

Clause 10. The device of any of clauses 1 to 9, wherein the MIM capacitor is a three-dimensional (3D) MIM capacitor formed in one or more metallization layers of the second side BEOL metallization.

Clause 11. The device of clause 10, wherein the 3D MIM capacitor is formed in a generally serpentine shape.

Clause 12. The device of any of clauses 10 to 11, wherein the 3D MIM capacitor is formed at least partially in a trench in one or more layers of the second side BEOL metallization.

Clause 13. The device of any of clauses 1 to 12, further comprising: a second MIM capacitor, wherein the second MIM capacitor is formed in a portion of the first side BEOL metallization.

Clause 14. The device of any of clauses 1 to 13, wherein the substrate is at least one of a bulk silicon substrate or a silicon on insulator (SOI) substrate.

Clause 15. The device of clause 14, wherein the substrate is the bulk silicon substrate having a thickness in a range of 10 nm to 500 nm.

Clause 16. A method of fabricating a device, the method comprising: forming a first side back end of line (BEOL) metallization on a substrate; forming a second side BEOL metallization on the substrate, wherein the substrate is disposed between the first side BEOL metallization and the second side BEOL metallization; and forming a metal-insulator-metal (MIM) capacitor in the second side BEOL metallization.

Clause 17. The method of clause 16, wherein forming the MIM capacitor comprises:

forming a first plate coupled to a first power connection; forming a second plate coupled to a second power connection; and forming a first insulator disposed between the first plate and the second plate.

Clause 18. The method of clause 17, wherein forming the MIM capacitor further comprises: forming a third plate coupled to the first power connection; and forming a second insulator disposed between the third plate and the second plate.

Clause 19. The method of clause 18, wherein forming the MIM capacitor further comprises: forming a fourth plate coupled to a third power connection; and forming a fifth plate coupled to the third power connection, wherein the second plate is disposed between the fourth plate and the fifth plate.

Clause 20. The method of clause 19, wherein the first insulator is disposed between the fourth plate and the second plate, and wherein a third insulator is disposed between the fifth plate and the second plate.

Clause 21. The method of clause 19, wherein the first insulator is disposed between the fourth plate and the second plate, and wherein the second insulator is disposed between the fifth plate and the second plate.

Clause 22. The method of any of clauses 17 to 21, wherein the first power connection is configured to be at a positive potential and wherein the second power connection is configured to be at a negative potential or ground.

Clause 23. The method of any of clauses 17 to 22, wherein the first insulator comprises a high dielectric constant (high-k) dielectric material and the first plate, the first insulator, and the second plate are disposed in an inter-metal dielectric (IMD) layer and wherein the IMD layer comprises a low dielectric constant (low-k) dielectric material.

Clause 24. The method of any of clauses 16 to 23, further comprising: forming at least one transistor on the substrate on a same side as the first side BEOL metallization.

Clause 25. The method of any of clauses 16 to 24, wherein the MIM capacitor is a three-dimensional (3D) MIM capacitor formed in one or more metallization layers of the second side BEOL metallization.

Clause 26. The method of clause 25, wherein the 3D MIM capacitor is formed in a generally serpentine shape.

Clause 27. The method of any of clauses 25 to 26, wherein the 3D MIM capacitor is formed at least partially in a trench in one or more layers of the second side BEOL metallization.

Clause 28. The method of any of clauses 16 to 27, further comprising: forming a second MIM capacitor, wherein the second MIM capacitor is formed in a portion of the first side BEOL metallization.

Clause 29. The method of any of clauses 16 to 28, wherein the substrate is at least one of a bulk silicon substrate or a silicon on insulator (SOI) substrate.

Clause 30. The method of clause 29, wherein the substrate is the bulk silicon substrate and further comprising: reducing a thickness of the bulk silicon substrate until the thickness of the bulk silicon substrate is in a range of 10 nm to 500 nm.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

1. A device comprising:
a first side back end of line (BEOL) metallization;
a second side BEOL metallization; and
a substrate disposed between the first side BEOL metallization and the second side BEOL metallization,
wherein the second side BEOL metallization comprises a metal-insulator-metal (MIM) capacitor.

2. The device of claim 1, wherein the MIM capacitor comprises:
a first plate coupled to a first power connection;
a second plate coupled to a second power connection; and
a first insulator disposed between the first plate and the second plate.

3. The device of claim 2, wherein the MIM capacitor further comprises
a third plate coupled to the first power connection; and
a second insulator disposed between the third plate and the second plate.

4. The device of claim 3, wherein the MIM capacitor further comprises:
a fourth plate coupled to a third power connection; and
a fifth plate coupled to the third power connection, wherein the second plate is disposed between the fourth plate and the fifth plate.

5. The device of claim 4, wherein the first insulator is disposed between the fourth plate and the second plate, and wherein a third insulator is disposed between the fifth plate and the second plate.

6. The device of claim 4, wherein the first insulator is disposed between the fourth plate and the second plate, and wherein the second insulator is disposed between the fifth plate and the second plate.

7. The device of claim 2, wherein the first power connection is configured to be at a positive potential and wherein the second power connection is configured to be at a negative potential or ground.

8. The device of claim 2, wherein the first insulator comprises a high dielectric constant (high-k) dielectric material and the first plate, the first insulator, and the second plate are disposed in an inter-metal dielectric (IMD) layer and wherein the IMD layer comprises a low dielectric constant (low-k) dielectric material.

9. The device of claim 1, further comprising:
at least one transistor formed on the substrate on a same side as the first side BEOL metallization.

10. The device of claim 1, wherein the MIM capacitor is a three-dimensional (3D) MIM capacitor formed in one or more metallization layers of the second side BEOL metallization.

11. The device of claim 10, wherein the 3D MIM capacitor is formed in a generally serpentine shape.

12. The device of claim 10, wherein the 3D MIM capacitor is formed at least partially in a trench in one or more layers of the second side BEOL metallization.

13. The device of claim 1, further comprising:
a second MIM capacitor, wherein the second MIM capacitor is formed in a portion of the first side BEOL metallization.

14. The device of claim 1, wherein the substrate is at least one of a bulk silicon substrate or a silicon on insulator (SOI) substrate.

15. The device of claim 14, wherein the substrate is the bulk silicon substrate having a thickness in a range of 10 nm to 500 nm.

16. A method of fabricating a device, the method comprising:
forming a first side back end of line (BEOL) metallization on a substrate;
forming a second side BEOL metallization on the substrate, wherein the substrate is disposed between the first side BEOL metallization and the second side BEOL metallization; and
forming a metal-insulator-metal (MIM) capacitor in the second side BEOL metallization.

17. The method of claim 16, wherein forming the MIM capacitor comprises:
forming a first plate coupled to a first power connection;
forming a second plate coupled to a second power connection; and
forming a first insulator disposed between the first plate and the second plate.

18. The method of claim 17, wherein forming the MIM capacitor further comprises:
forming a third plate coupled to the first power connection; and
forming a second insulator disposed between the third plate and the second plate.

19. The method of claim 18, wherein forming the MIM capacitor further comprises:
forming a fourth plate coupled to a third power connection; and
forming a fifth plate coupled to the third power connection, wherein the second plate is disposed between the fourth plate and the fifth plate.

20. The method of claim 19, wherein the first insulator is disposed between the fourth plate and the second plate, and wherein a third insulator is disposed between the fifth plate and the second plate.

21. The method of claim 19, wherein the first insulator is disposed between the fourth plate and the second plate, and wherein the second insulator is disposed between the fifth plate and the second plate.

22. The method of claim 17, wherein the first power connection is configured to be at a positive potential and wherein the second power connection is configured to be at a negative potential or ground.

23. The method of claim 17, wherein the first insulator comprises a high dielectric constant (high-k) dielectric material and the first plate, the first insulator, and the second plate are disposed in an inter-metal dielectric (IMD) layer and wherein the IMD layer comprises a low dielectric constant (low-k) dielectric material.

24. The method of claim 16, further comprising:
forming at least one transistor on the substrate on a same side as the first side BEOL metallization.

25. The method of claim 16, wherein the MIM capacitor is a three-dimensional (3D) MIM capacitor formed in one or more metallization layers of the second side BEOL metallization.

26. The method of claim 25, wherein the 3D MIM capacitor is formed in a generally serpentine shape.

27. The method of claim 25, wherein the 3D MIM capacitor is formed at least partially in a trench in one or more layers of the second side BEOL metallization.

28. The method of claim 16, further comprising:
forming a second MIM capacitor, wherein the second MIM capacitor is formed in a portion of the first side BEOL metallization.

29. The method of claim 16, wherein the substrate is at least one of a bulk silicon substrate or a silicon on insulator (SOI) substrate.

30. The method of claim 29, wherein the substrate is the bulk silicon substrate and further comprising:
reducing a thickness of the bulk silicon substrate until the thickness of the bulk silicon substrate is in a range of 10 nm to 500 nm.
